(19) United States
(12) Patent Application Publication
(10) Pub. No.: US 2006/0109000 A1
(43) Pub. Date: May 25, 2006

(54) Defect inspection method for perpendicular magnetic recording medium, magnetic disk device, and method of registering defects in magnetic disk device having a perpendicular magnetic recording medium therein

(75) Inventors: Kiyoshi Makino, Kanagawa (JP); Yoshibumi Matsuda, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global Storage Technologies Netherlands B.V., AZ Amsterdam (NL)

(21) Appl. No.: 11/286,130

(22) Filed: Nov. 22, 2005

(30) Foreign Application Priority Data
Nov. 24, 2004 (JP) 2004-338478

(51) Int. Cl. G01R 33/12

(52) U.S. Cl. 324/212

(57) ABSTRACT

Because of its characteristics, a perpendicular magnetic recording medium has the inconvenience that since sections with low signal stability due to magnetic defects are not easily detectible in advance, these sections are detected after mounting of the medium in a magnetic disk device or after product shipping. According to one embodiment, in the manufacturing processes for the perpendicular magnetic recording medium, a DC-erase process step for direct-current demagnetizing the medium is performed after a magnetic film deposition process step and a lubricating-agent application process step. This maximizes the effects of a demagnetizing field and intentionally increases directional instability of magnetization. After the above processes, the medium is further provided with a heating process to accelerate the reversal of magnetization in latent defective sections. A defect examination step for detecting the magnetization reversal sections on the basis of changes in the baseline of the signal read out from the medium under the above state is performed, whereby defects can be detected efficiently.

### CROSS-REFERENCES TO RELATED APPLICATIONS

This application claims priority from Japanese Patent Application No. JP2004-338478, filed Nov. 24, 2004, the entire disclosure of which is incorporated herein by reference.

### BACKGROUND OF THE INVENTION

The present invention relates to a defect inspection method for a perpendicular magnetic recording medium, to a magnetic disk device, and to a method of registering defects in a magnetic disk device having a perpendicular magnetic recording medium therein.

Storage devices based on magnetic recording technology are most commonly used in products such as computers, workstations, and digital electrical household appliances. In recent years, the extension of these storage devices in storage capacity has been increasingly accelerated with increases in the volumes of information recorded. The storage devices under these situations include magnetic disk devices available at relatively low prices and capable of achieving both a high read/write speed and a large storage capacity.

Longitudinal magnetic recording for magnetizing a magnetic recording medium (hereinafter, referred to simply as the medium) in a direction parallel to the surface of the medium has been adopted as the conventional magnetic recording scheme. Nowadays, however, the perpendicular magnetic recording scheme is being brought to attention. The perpendicular magnetic recording scheme is intended to record signals by conducting magnetization perpendicular to the medium surface. This scheme can improve recording density over that of the longitudinal magnetic recording scheme and also suppress signal deterioration coupled with the improvement of recording density. Accordingly, the adoption of the perpendicular magnetic recording scheme is expected to be accelerated in the future.

After the manufacture of a medium to be used in a magnetic disk device (hereinafter, referred to simply as the recording device), the medium, before being built into the recording device, is inspected to determine whether the medium can withstand its usage in the recording device. Inspection for smoothness of the entire medium surface by use of a head having a mounted piezoelectric element, and the inspection of signal quality by read/write operations are conducted as conventional medium independent inspections.

If any such defects in the manufacture of the medium that are likely to affect magnetic recording are detected in the above inspections, when the number of defects is not too great, the occurrence of trouble with the operation of the recording device in which the medium is to be mounted can be prevented by registering the positions of the defects in the device and avoiding the use of the particular defective sections. When the number of defects is too great, however, the defect registration method does not suffice to prevent the operational performance of the recording device from decreasing. Accordingly, a measure such as not using that medium is taken if the number of defects is greater than its required upper-limit value. An example of existing art is Japanese Patent Laid-Open No. 2004-199733.

### BRIEF SUMMARY OF THE INVENTION

Because of its characteristics, the perpendicular magnetic recording type of medium (perpendicular magnetic recording medium) is most susceptible to the demagnetizing field that causes adjacent regions to act on one another when bits of the same value are written in succession. In particular, if manufacturing-related, very small, nonuniform sections occur, this easily causes the reversal of magnetization due to the demagnetizing field. Accordingly, even if the desired direction of magnetization can be given in the perpendicular magnetic recording medium by the write operation, sections in which the magnetization becomes unstable and easily reverses are likely to be formed longitudinally inside the medium. Manufacturing-related nonuniform sections include, for example, very small depressions and projections on the surface of a substrate, and the sections where these depressions and projections are present tend to suffer the reversal of magnetization. Not all these sections, however, suffer the reversal.

There has been the problem that these sections prone to suffer the reversal of magnetization under the influence of a demagnetizing field are difficult to accurately detect during the signal read/write inspections and air-bearing surface asperity measurements performed in the conventional disk independent inspection process taking place before the reversal actually occurs.

In other words, there has been the following inconvenience. That is, since defective sections prone to suffer the reversal of magnetization become elicited primarily after medium mounting in the storage device, the number of defects registered is likely to exceed an upper-limit value and increase the frequency of storage device repair associated with medium replacement during the inspections in the processes following medium mounting in the storage device. In addition, a situation in which the corresponding defective sections become elicited after product shipping should be avoided as much as possible.

The present invention has been made for solving the above problems, and a feature of the invention is to provide a defect inspection method that allows efficient detection of defects in a perpendicular magnetic recording medium, especially of defects due to magnetization reversal. Another feature of the invention is to provide a magnetic disk device in which are suppressed the decreases in device performance and signal reliability that are likely to result from signal quality deterioration due to defects. Yet another feature of the invention is to provide an accuracy-improved method for registering defects in a magnetic disk device.

A defect inspection method for a perpendicular magnetic recording medium according to an embodiment of the present invention includes: a demagnetizing step for direct-current erasing the perpendicular magnetic recording medium, followed by a heating step for heating the perpendicular magnetic recording medium, further followed by a defect examination step for detecting a magnetic field on the surface of the perpendicular magnetic recording medium and examining, from changes in the magnetic field, whether defective sections are present in the perpendicular magnetic recording medium.

A magnetic disk device according to an embodiment of the present invention includes: a perpendicular magnetic recording medium which, after being provided with a direct-current erasing process first and then a heating process, is already inspected for defective sections, on the basis of changes in the magnetic field detected on the surface of the medium; and a storage element in which position information on detected defective sections is already registered.

A method for registering defects in a magnetic disk device according to another embodiment of the present invention includes: a heating step for heating the magnetic disk device in its entirety after a perpendicular magnetic recording medium with a magnetic field erased by a direct current and with servo data written onto the medium has been mounted in the magnetic disk device; and a defect registration step for, after the heating step, performing a read operation on the perpendicular magnetic recording medium and detecting and registering defect positions thereof on the basis of changes in the read signals sent from direct-current erased sections.

According to the present invention, a signal present on a perpendicular magnetic recording medium is rendered unstable by direct-current erasing, and then the coercivity of the medium is deteriorated by heating it to accelerate the reversal of magnetization in defective sections. It is possible, by conducting defect inspections after that, to efficiently detect defects in the medium, more particularly, defects due to magnetization reversal. Also, registering detected defects in a similar manner in a magnetic disk device improves registration accuracy of the defects. In addition, it is possible to obtain a magnetic disk device whose decreases in device performance and signal reliability due to defects are suppressed.

### BRIEF DESCRIPTION OF THE DRAWINGS

FIG. 1 is a flow diagram explaining an example of a defect inspection method for a perpendicular magnetic recording medium according to an embodiment of the present invention.

FIG. 2 is a schematic diagram showing an example of a medium-processing apparatus usable in the present inspection method.

FIG. 3 is a schematic diagram showing an example of an inspection apparatus usable in the present inspection method.

FIG. 4 is a flow diagram explaining another example of a defect inspection method for a perpendicular magnetic recording medium according to another embodiment of the present invention.

FIG. 5 is a schematic plan view of a 2.5-inch magnetic disk device.

FIG. 6 is a flow diagram of a first example showing a process flow for inspecting defects with a medium built into a recording device.

FIG. 7 is a flow diagram of a second example showing a process flow for inspecting defects with a medium built into a recording device.

FIG. 8 is a flow diagram of a third example showing a process flow for inspecting defects with a medium built into a recording device.

FIG. 9 is a graph for comparing the number of defects which were detected in an independent status of unheated media, and the number of defects detected in heated media.

FIG. 10 is a graph that shows distributions of the number of defects which were registered in a defect registration process.

### DETAILED DESCRIPTION OF THE INVENTION

Modes of embodiment of the present invention (hereinafter, referred to simply as embodiments) are described hereunder, pursuant to the accompanying drawings.

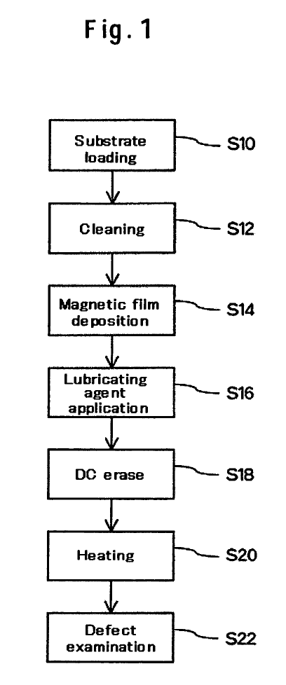

FIG. 1 is a flow diagram that explains a defect inspection method for a perpendicular magnetic recording medium according to an embodiment of the present invention. The diagram also outlines manufacturing process steps for the medium. This defect inspection method is intended to inspect defects in the medium alone before it is built into a recording device. The medium is manufactured using, for example, an aluminum substrate provided with Ni—P plating. After being loaded for manufacturing processes in step S10, the substrate is cleaned in step S12 as a pre-process for depositing a magnetic film on the medium. Cleaning process step S12 may be preceded by a process step for forming depressions and projections on the substrate surface. After cleaning process step S12, a magnetic film with perpendicular magnetic anisotropy is deposited on the substrate surface in step S14. In magnetic-film deposition step S14, a magnetic film of a Co alloy, for example, is formed on the substrate surface by sputtering, and a protective film for improved durability and corrosion resistance is further formed on the magnetic film. Next, the substrate is coated with a lubricating agent to form a lubricating layer as a top layer on the substrate surface in step S16. A medium formed with depressions and projections on an underlayer or on a protective layer, by use of a glass substrate, is also manufactured.

The medium that has been formed by undergoing these process steps is then provided with a direct-current (DC) erase process in step S18. In DC-erase process step S18, a method of demagnetizing the entire medium at a time can be adopted to improve throughput. For example, the entire surface of the medium is uniformly demagnetized by arranging a pair of electromagnets or permanent magnets, each sufficiently larger than the medium in terms of diameter, in an opposed form at fixed intervals, and interposing the medium between the magnets. For example, DC-erasing a medium that uses a 2.5-inch disk device can use cylindrical magnets both measuring 20 cm in diameter. When a pair of electromagnets is used, the medium is inserted between the pair of electromagnets and then an electric current is supplied to both electromagnets so that magnetization of the magnetic film on the medium is oriented in either one direction perpendicular thereto. After the orientation, supply of the current to the electromagnets is stopped and then the medium is removed from an interspace between the electromagnets. When a pair of permanent magnets is used, the medium is inserted into an interspace between the pair of permanent magnets and then after separation of the permanent magnets from the medium at a fixed speed, the medium is removed. A method of demagnetizing the medium track-by-track can also be adopted for a magnetic head that is to be inspected.

Next, the DC-erased medium is heated in step S20. Heating process step S20 can be performed for one medium at a time. Alternately, however, entire transfer cases each containing a plurality of media can be loaded, one by one, into a hot chamber and then process step S20 can be performed for each transfer case independently. For example, the medium is allowed to stay for 30 minutes in a hot chamber preset to 100° C. The heating temperature and time required are set according to particular characteristics of the medium so that a purpose of this process step to accelerate magnetization reversal due to a demagnetizing field is achieved. The heating method that can be applied is not limited to hot-chamber usage, and any other method is adoptable that permits a stabilized temperature to be applied to the medium. Heating is likewise possible by using, for example, a laser or a halogen lamp.

Heating is followed by step S22, in which defect examinations are performed to examine the inside of the medium for defective sections by measuring the magnetic field occurring on the surface of the medium. The magnetic field measurement in defect examination step S22, as with signal quality inspection in a normal read/write inspection process, can use a magnetic head. However, write operation is not executed and only read operation is executed. Changes in a baseline of the signal obtained from the magnetic head during the read operation are detected and thus, defective sections in which magnetization is being reversed are detected. Defects that have been generated in the medium by heating basically remain therein, even after the medium has been cooled down to ordinary temperature. Defect examination step S22 can therefore be performed at ordinary temperature.

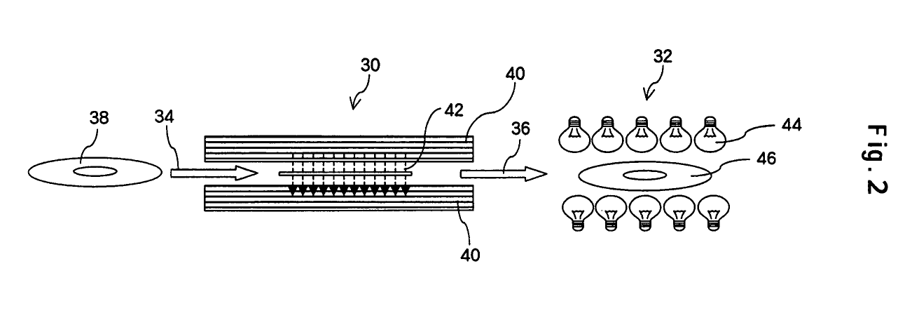

FIG. 2 is a schematic diagram showing an example of a medium-processing apparatus usable in the present inspection method. The apparatus shown in FIG. 2 performs DC-erase process step S18 and heating process step S20, and are constituted by and inclusive of an erase unit 30, a heating unit 32, and transfer mechanisms 34 and 36. Media 38, after being carried in from the lubricating-agent application process in step S116, is inserted, one piece at a time, in parallel into an interspace between one pair of electromagnets 40 within the erase unit 30 by the transfer mechanism 34. Each medium is then DC-erased by a magnetic field 42 applied perpendicularly to the interspace. The thus-erased medium is removed from the interspace of the electromagnets 40, and transferred to the heating unit 32, by the transfer mechanism 36. The heating unit 32 is constructed so that the infrared rays (or the like) radiated from halogen lamps 44 are irradiated uniformly onto both the surface and reverse of the medium. A medium 46 that has thus been heated by the heating unit 32 is removed from the processing apparatus and then transferred for the defect examination process in step S22. The transfer mechanisms 34 and 36 are constituted using a nonmagnetic material.

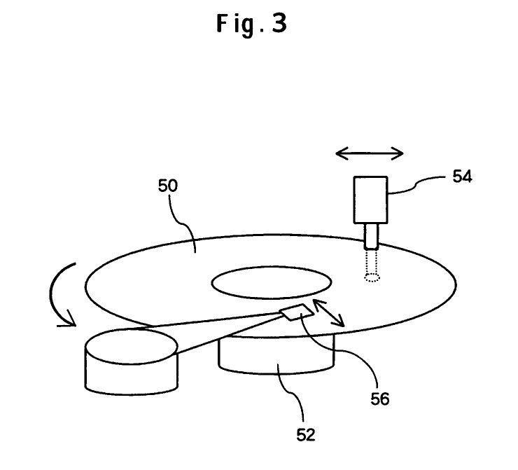

FIG. 3 is a schematic diagram showing an example of an inspection apparatus usable in the present inspection method. The apparatus shown in FIG. 3 performs heating process step S20 and defect examination step S22 in parallel on the same medium. Medium 50 to be inspected is rotated by a spindle motor 52. A heating unit 54 for irradiating laser light onto the surface of the medium 50, and a magnetic head 56 for scanning the medium surface are provided. The heating unit 54 outputs spot-shaped laser light and sequentially heats cylindrical regions in accordance with rotation of the medium 50. The heating unit 54 has a driver and can move in a radial direction of the medium 50, and movement of the laser light spot and the rotation of the medium allow the entire surface of the medium 50 to be heated. The magnetic head 56 moves to seek for a heated track, performs a read operation on the track, and detects defects using the signal obtained from the read operation. The heating unit 54 and the magnetic head 56 are provided at both sides of the medium 50 and can be adapted to heat and inspect both the surface and reverse of the medium 50 at the same time.

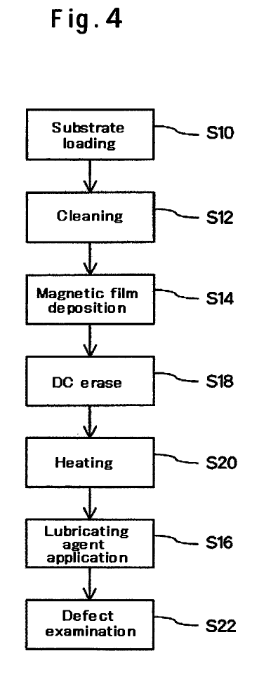

If the lubricating agent applied to the medium suffers effects such as thermal modification by heating, DC-erase process step S18 and heating process step S20 can precede lubricating-agent application process step S16, as shown in a flow diagram of FIG. 4.

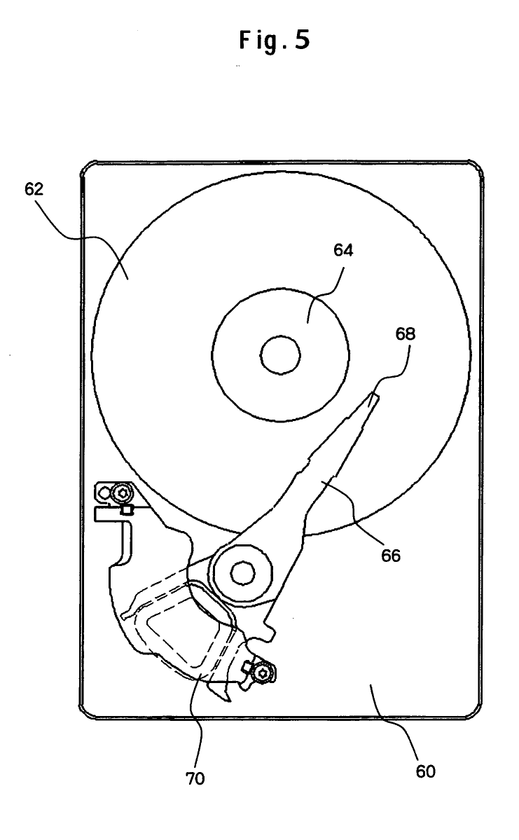

The above-described embodiment is an inspection method executed in an independent state of media. In this case, after defect examination step S22 have been performed, the media satisfying, for example, the condition that the number of defects detected in the examination should be equal to or less than a required value, is selected and then assembled into such a recording device as shown in FIG. 5. FIG. 5 is a schematic plan view of a 2.5-inch recording device. A medium 62 that has been inspected using the above-mentioned inspection method is disposed in a housing 60 of the recording device. Next, the medium 62 is installed on a shaft rotated by the spindle motor, by use of a hub and a clamp 64. Magnetic head 68 installed at a leading edge of a head arm 66 is held adjacently to the surface of the medium 62, and performs read/write operations on the medium 62. The head arm 66 is pivoted around its fulcrum by a voice coil motor 70, and moves the magnetic head 68 to a radial position on the medium to implement a seek operation. The recording device can be adapted to register, in its storage element, position information on defects present in the medium 62, and when the recording device is operated, use the information so as to avoid using defective sections. The defect positions can be registered by, after the medium 62 has been built into the recording device, searching for the defect positions by use of the magnetic head 68 in a DC-erased state, i.e., before a write operation is performed, as in defect examination process step S22, and then storing addresses of detected defects into the storage element.

The heating process step S20 or both DC-erase process step S18 and heating process step S20 mentioned in the description of the inspection method executed in an independent medium state may also be performed after the medium has been mounted in the recording device. When defect examination is to follow the mounting of the medium in the recording device, a defect registration process step for conducting the above-mentioned defect registration process can be further combined with the defect examination.

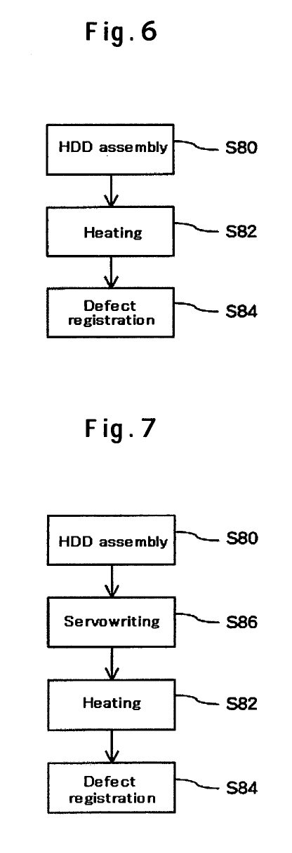

FIGS. 6 to 8 are flow diagrams each showing the different process flow applied when defects are inspected with a medium built into a recording device. FIG. 6 shows the process flow applied when process steps up to a DC-erase step are performed in an independent medium state beforehand and then after servo data writing onto the medium by means of a servowriter, the medium is built into the recording device. In this case, HDD assembly process step S80 for assembling the medium and other recording device components into the state shown in FIG. 5 is followed by heating process step S82 first and then defect registration process step S84.

FIG. 7 shows the process flow applied when the medium that has undergone process steps up to the DC-erase step in the independent state of the medium is already built into the recording device without servo data being written thereonto. In this case, HDD assembly process step S80 for assembling the medium and other recording device components is followed by servowrite process step S86, which is further followed by heating process step S82 first and then defect registration process step S84.

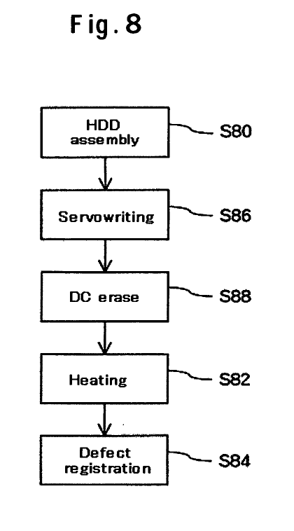

FIG. 8 shows the process flow applied when the medium is already built into the recording device without being DC-erased in the independent state of the medium. In this case, HDD assembly process step S80 for assembling the medium and other recording device components is followed by servowrite process step S86, which is further followed by DC-erase step S88, heating process step S82, and defect registration process step S84, in that order.

Heating process step S82 for the medium after being built into the recording device can use, for example, a conventional heating-type tester to heat the entire recording device. Also, DC-erase step S88 can use the magnetic head 68 of the recording device to demagnetize the medium, track by track. At this time, the demagnetization is executed for all user data regions on tracks, except for servo regions.

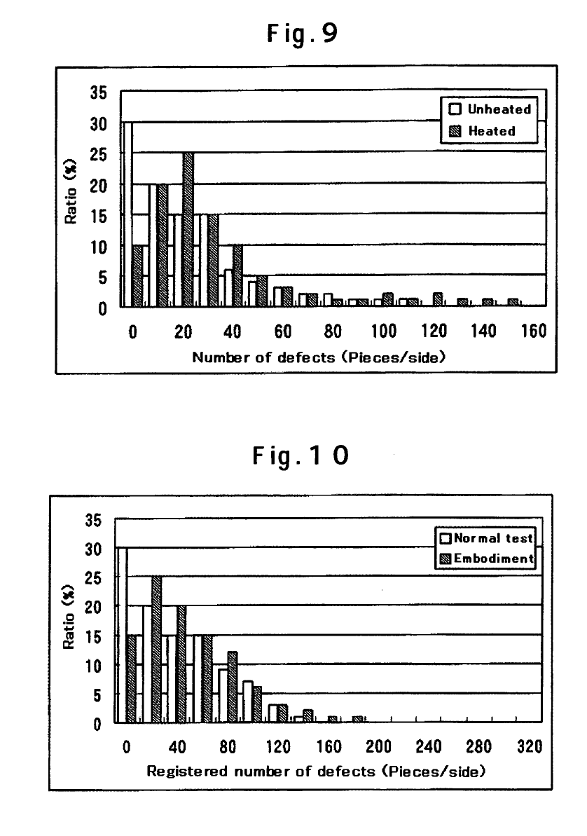

FIG. 9 is a graph for comparing the number of defects which were detected in an independent status of unheated media, and the number of defects detected in heated media. In FIG. 9, the number of internal defects per side of each medium is shown in separated form for every 10 pieces, on a horizontal axis, and a ratio of the number of samples falling within each graphic interval of the horizontal axis, to the total number of samples, is shown on a vertical axis. The left bar shown in each graphic interval represents unheated-medium defect samples, and the right bar shown in the interval represents heated-medium defect samples. This graph indicates an increase in the number of defects detected after heating, above that of defects detected before heating. This means that the defects that remained latent in the perpendicular magnetic recording medium until it was heated are elicited by the heating process, and indicates that defects not detectible by normal read/write testing can be detected in the present inspection method.

FIG. 10 is a graph that shows distributions of the number of defects which were registered in defect registration process step S84. In FIG. 10, the number of internal defects per side of each medium is shown in separated form for every 20 pieces, on a horizontal axis, and a ratio of the number of samples falling within each graphic interval of the horizontal axis, to the total number of samples, is shown on a vertical axis. The total number of recording devices which were used to evaluate defect registration accuracy is 300, and two media each capable of recording on both sides are mounted in each device. Hence, the total number of sampled sides of media is 1,200. The left bar shown in each graphic interval represents, as a comparative example, data based on the number of defects which were registered in a normal defect registration test process. In FIG. 10 is represented the number of defects registered during read/write operations with temperature upper-limit data settings of temperature environmental specifications of the defect registration test process (i.e., 55° C. for the evaluated recording devices, about 62° C. as an internal temperature thereof). The right bar shown in the interval represents the results obtained in defect registration process step S84 of the above-described embodiment. Data from which defects other than those due to the medium have been excluded beforehand is shown in FIG. 10. It can be seen from these results that despite the use of the recording devices of the same specifications, the distribution based on execution of defect registration process step S84 according to the above-described embodiment has a peak shifted to the side having a greater registration of defects than in the comparative example. In other words, this indicates that more accurate defect detection and, hence, more accurate defect registration are realized by registering defects in defect registration process step S84 of the embodiment, than by conducting defect registration based on the normal read/write operations performed under a high-temperature environment.

As described above, the present defect inspection method makes it possible to detect defects in a perpendicular magnetic recording medium very accurately and exclude defective media effectively, and improves a recording device in quality. In addition, the occurrence of a situation in which defects not registered will later become elicited and affect the operation of the recording device is suppressed since highly accurate defect registration is implemented.

It is to be understood that the above description is intended to be illustrative and not restrictive. Many embodiments will be apparent to those of skill in the art upon reviewing the above description. The scope of the invention should, therefore, be determined not with reference to the above description, but instead should be determined with reference to the appended claims alone with their full scope of equivalents.

What is claimed is:

1. A defect inspection method for a perpendicular magnetic recording medium, comprising:
a demagnetizing step including direct-current erasing magnetism from the perpendicular magnetic recording medium;
a heating step including heating the perpendicular magnetic recording medium after execution of said demagnetizing step; and
a defect examination step including, after execution of said heating step, detecting a magnetic field present on the surface of the perpendicular magnetic recording medium, and then on the basis of changes in the magnetic field, examining whether defective sections are present in the perpendicular magnetic recording medium.

2. The defect inspection method according to claim 1, wherein:
each of said steps is conducted with the perpendicular magnetic recording medium mounted in a magnetic disk device.

3. The defect inspection method according to claim 1, wherein:
said demagnetizing step is conducted before the perpendicular magnetic recording medium is mounted in a magnetic disk device; and
said heating step and said defect examination step are conducted with the perpendicular magnetic recording medium mounted in the magnetic disk device.

4. The defect inspection method according to claim 3, wherein said heating step and said defect examination step are conducted simultaneously.

5. The defect inspection method according to claim 1, wherein said heating step and said defect examination step are conducted simultaneously.

6. The defect inspection method according to claim 1, wherein:
said demagnetizing step and said heating step are conducted before the perpendicular magnetic recording medium is mounted in a magnetic disk device; and
said defect examination step is conducted with the perpendicular magnetic recording medium mounted in the magnetic disk device.

7. The defect inspection method according to claim 1, wherein said heating step comprises irradiating light onto a surface of said perpendicular magnetic recording medium.

8. The defect inspection method according to claim 1, wherein said defect examination step comprises scanning a surface of said perpendicular magnetic recording medium with a magnetic head.

9. The defect inspection method according to claim 1, further comprising applying a lubricating agent on said perpendicular magnetic recording medium before said defect examination step.

10. The defect inspection method according to claim 9, wherein the lubricating agent is applied after the heating step.

11. The defect inspection method according to claim 9, wherein the lubricating agent is applied before the demagnetizing step and the heating step.

12. A magnetic disk device, comprising:
a perpendicular magnetic recording medium which, after being provided with a direct-current demagnetizing process first and then a heating process, is subjected to inspection for defective sections, based on changes in the magnetic field detected on the surface of the medium; and
a storage element with registered position information on the defective sections.

13. A method for registering defects in a magnetic disk device having a perpendicular magnetic recording medium, said method comprising:
heating the magnetic disk device having mounted therein the perpendicular magnetic recording medium which was direct-current demagnetized and onto which servo data was written; and
after execution of said heating step, performing a read operation on the perpendicular magnetic recording medium, and then on the basis of changes in the read signal sent from a direct-current demagnetized section, detecting and registering defect positions of the perpendicular magnetic recording medium.

14. The defect registration method according to claim 13, further comprising:
writing the servo data onto the direct-current demagnetized perpendicular magnetic recording medium prior to heating the magnetic disk device.

15. The defect registration method according to claim 13, further comprising:
writing the servo data onto the direct-current demagnetized perpendicular magnetic recording medium prior to heating the magnetic disk device; and
conducting direct-current demagnetization by performing a write operation on a user data region of the perpendicular magnetic recording medium with the servo data written thereonto.
